(19) United States
(12) Patent Application Publication
(10) Pub. No.: US 2025/0169148 A1
(43) Pub. Date: May 22, 2025

(54) SEMICONDUCTOR DEVICE

(71) Applicants: KABUSHIKI KAISHA TOSHIBA, Tokyo (JP); TOSHIBA ELECTRONIC DEVICES & STORAGE CORPORATION, Tokyo (JP)

(72) Inventors: Aya SHINDOME, Yokohama (JP); Yosuke KAJIWARA, Yokohama (JP); Masahiko KURAGUCHI, Yokohama (JP); Hiroshi ONO, Setagaya (JP)

(73) Assignees: KABUSHIKI KAISHA TOSHIBA, Tokyo (JP); TOSHIBA ELECTRONIC DEVICES & STORAGE CORPORATION, Tokyo (JP)

(21) Appl. No.: 18/761,403

(22) Filed: Jul. 2, 2024

(30) Foreign Application Priority Data
Nov. 16, 2023 (JP) 2023-194829
May 22, 2024 (JP) 2024-083077

(51) Int. Cl. H01L 29/423; H01L 29/04; H01L 29/06; H01L 29/20; H01L 29/778

(52) U.S. Cl. CPC H10D 64/514; H10D 62/124; H10D 62/40; H10D 62/8503; H10D 30/47

(57) ABSTRACT

According to one embodiment, a semiconductor device includes a first electrode, a second electrode, a third electrode, and a semiconductor member. The first to third electrodes extend along a first direction. A second direction from the first electrode to the second electrode crosses the first direction. The third electrode includes a first electrode portion and a second electrode portion. The semiconductor member includes a first semiconductor layer including Alₓ₁Ga₁₋ₓ₁N (0≤x1<1), and a second semiconductor layer including Alₓ₂Ga₁₋ₓ₂N (0<x2≤1, x1<x2). The first semiconductor layer includes a first partial region, a second partial region, a third partial region, a fourth partial region, a fifth partial region, a sixth partial region, and a seventh partial region. direction. The second semiconductor layer includes a first semiconductor portion, a second semiconductor portion, a third semiconductor portion, and a fourth semiconductor portion.

### CROSS-REFERENCE TO RELATED APPLICATIONS

This application is based upon and claims the benefit of priority from Japanese Patent Application No. 2023-194829, filed on Nov. 16, 2023, and Japanese Patent Application No. 2024-83077, filed on May 22, 2024; the entire contents of which are incorporated herein by reference.

### FIELD

Embodiments described herein relate generally to a semiconductor device.

### BACKGROUND

For example, it is desired to improve the characteristics of semiconductor devices such as transistors.

### BRIEF DESCRIPTION OF THE DRAWINGS

FIG. 1 is a schematic plan view illustrating a semiconductor device according to a first embodiment;

FIG. 2 is a schematic cross-sectional view illustrating the semiconductor device according to the first embodiment;

FIG. 3 is a schematic cross-sectional view illustrating the semiconductor device according to the first embodiment;

FIG. 4 is a schematic plan view illustrating a semiconductor device according to the first embodiment;

FIG. 5 is a schematic plan view illustrating a semiconductor device according to a second embodiment;

FIG. 6 is a schematic cross-sectional view illustrating the semiconductor device according to the second embodiment;

FIG. 7 is a schematic plan view illustrating a semiconductor device according to a third embodiment;

FIG. 8 is a schematic cross-sectional view illustrating the semiconductor device according to the third embodiment; and

FIG. 9 is a schematic plan view illustrating a semiconductor device according to the third embodiment.

### DETAILED DESCRIPTION

According to one embodiment, a semiconductor device includes a first electrode, a second electrode, a third electrode, and a semiconductor member. The first electrode extends along a first direction. The second electrode extends along the first direction. A second direction from the first electrode to the second electrode crosses the first direction. The third electrode extends along the first direction. A position of the third electrode in the second direction is between a position of the first electrode in the second direction and a position of the second electrode in the second direction. The third electrode includes a first electrode portion and a second electrode portion. The second electrode portion is electrically connected to the first electrode portion. The semiconductor member includes a first semiconductor layer including Alₓ₁Ga₁₋ₓ₁N (0≤x1<1), and a second semiconductor layer including Alₓ₂Ga₁₋ₓ₂N (0<x2≤1, x1<x2). The first semiconductor layer includes a first partial region, a second partial region, a third partial region, a fourth partial region, a fifth partial region, a sixth partial region, and a seventh partial region. A direction from the first partial region to the first electrode is along a third direction crossing a plane including the first direction and the second direction. A direction from the second partial region to the second electrode is along the third direction. A direction from the third partial region to the first electrode portion is along the third direction. A position of the fourth partial region in the second direction is between a position of the first partial region in the second direction and a position of the third partial region in the second direction. The position of the fifth partial region in the second direction is between the position of the third partial region in the second direction and a position of the second partial region in the second direction. A position of the third partial region in the first direction is between a position of the seventh partial region in the first direction and a position of the sixth partial region in the first direction. The second semiconductor layer includes a first semiconductor portion, a second semiconductor portion, a third semiconductor portion, and a fourth semiconductor portion. A direction from the fourth partial region to the first semiconductor portion is along the third direction. A direction from the fifth partial region to the second semiconductor portion is along the third direction. A direction from the sixth partial region to the third semiconductor portion is along the third direction. A direction from the seventh partial region to the fourth semiconductor portion is along the third direction. The third semiconductor portion is provided between the sixth partial region and the second electrode portion in the third direction. At least a part of the first electrode portion is between the first semiconductor portion and the second semiconductor portion in the second direction. The at least the part of the first electrode portion is between the fourth semiconductor portion and the third semiconductor portion in the first direction. A first electrode portion thickness of the first electrode portion along the third direction is thicker than a second electrode portion thickness of the second electrode portion along the third direction.

Various embodiments are described below with reference to the accompanying drawings. The drawings are schematic and conceptual; and the relationships between the thickness and width of portions, the proportions of sizes among portions, etc., are not necessarily the same as the actual values. The dimensions and proportions may be illustrated differently among drawings, even for identical portions.

In the specification and drawings, components similar to those described previously or illustrated in an antecedent drawing are marked with like reference numerals, and a detailed description is omitted as appropriate.

### First Embodiment

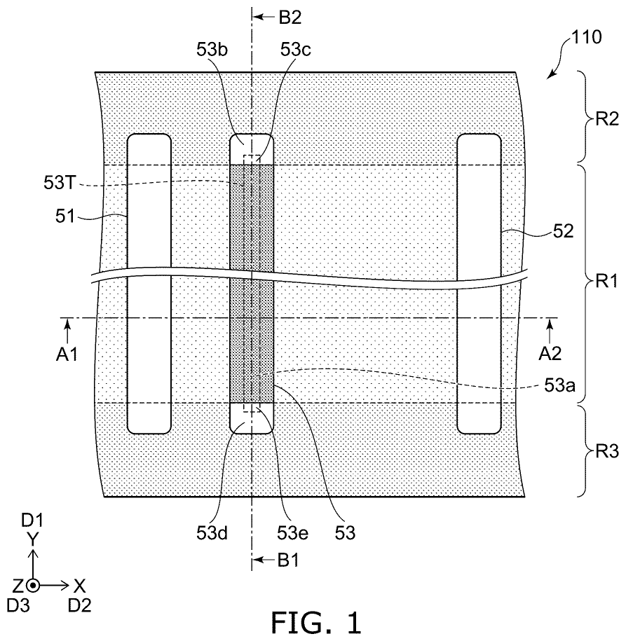

FIG. 1 is a schematic plan view illustrating a semiconductor device according to a first embodiment.

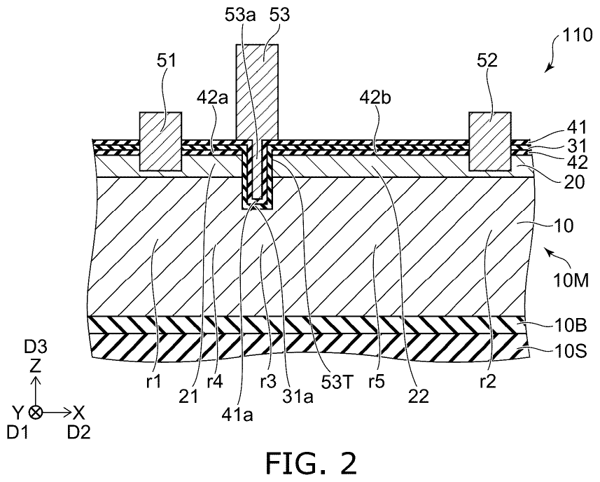

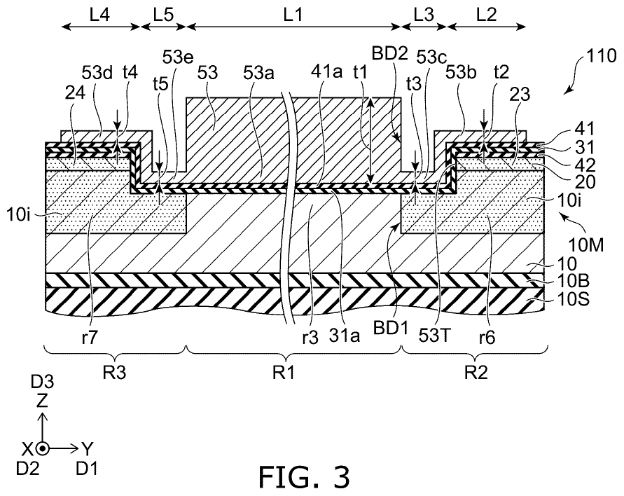

FIGS. 2 and 3 are schematic cross-sectional views illustrating the semiconductor device according to the first embodiment.

FIG. 2 is a sectional view taken along the line A1-A2 in FIG. 1. FIG. 3 is a sectional view taken along the line B1-B2 in FIG. 1.

As shown in FIGS. 1 to 3, a semiconductor device 110 according to the embodiment includes a first electrode 51, a second electrode 52, a third electrode 53, and a semiconductor member 10M. The semiconductor member 10M includes a first semiconductor layer 10 and a second semiconductor layer 20.

The first electrode 51, the second electrode 52, and the third electrode 53 extend along a first direction D1. The first direction D1 is a Y-axis direction. One direction perpendicular to the Y-axis direction is defined as an X-axis direction. One direction perpendicular to the Y-axis direction and the X-axis direction is defined as a Z-axis direction. In each of these electrodes, the length in the Y-axis direction is longer than the length in the X-axis direction and longer than the length in the Z-axis direction.

A second direction D2 from the first electrode 51 to the second electrode 52 crosses the first direction D1. The second direction D2 is, for example, the X-axis direction.

A position of the third electrode 53 in the second direction D2 is between a position of the first electrode 51 in the second direction D2 and a position of the second electrode 52 in the second direction D2. The third electrode 53 includes a first electrode portion 53a and a second electrode portion 53b. The second electrode portion 53b is electrically connected to the first electrode portion 53a. The first electrode portion 53a extends along the first direction D1.

The first semiconductor layer 10 includes Alₓ₁Ga₁₋ₓ₁N (0≤x1<1). The composition ratio x1 may be, for example, not less than 0 and less than 0.13. The first semiconductor layer 10 may be GaN or AlGaN.

The second semiconductor layer 20 includes Alₓ₂Ga₁₋ₓ₂N (0<x2≤1, x1<x2). The composition ratio x2 may be, for example, not less than 0.13 and not more than 0.4. The second semiconductor layer 20 includes, for example, AlGaN.

The first semiconductor layer 10 includes a first partial region r1, a second partial region r2, a third partial region r3, a fourth partial region r4, a fifth partial region r5, a sixth partial region r6, and a seventh partial region r7. A direction from the first partial region r1 to the first electrode 51 is along a third direction D3.

As shown in FIG. 2, the third direction D3 crosses a plane including the first direction D1 and the second direction D2. The third direction D3 is, for example, the Z-axis direction. A direction from the second partial region r2 to the second electrode 52 is along the third direction D3. A direction from the 15 third partial region r3 to the first electrode portion 53a is along the third direction D3.

As shown in FIG. 2, a position of the fourth partial region r4 in the second direction D2 is between a position of the first partial region r1 in the second direction D2 and a position of the 20 third partial region r3 in the second direction D2. A position of the fifth partial region r5 in the second direction D2 is between the position of the third partial region r3 in the second direction D2 and a position of the second partial region r2 in the second direction D2.

As shown in FIG. 3, the position of the third partial region r3 in the first direction D1 is between a position of the seventh partial region r7 in the first direction D1 and a position of the sixth partial region r6 in the first direction D1.

As shown in FIGS. 2 and 3, the second semiconductor layer 20 includes a first semiconductor portion 21, a second semiconductor portion 22, a third semiconductor portion 23, and a fourth semiconductor portion 24. As shown in FIG. 2, a direction from the fourth partial region r4 to the first semiconductor portion 21 is along the third direction D3. A 35 direction from the fifth partial region r5 to the second semiconductor portion 22 is along the third direction D3.

As shown in FIG. 3, a direction from the sixth partial region r6 to the third semiconductor portion 23 is along the third direction D3. A direction from the seventh partial region r7 to the fourth semiconductor portion 24 is along the third direction D3. The third semiconductor portion 23 is provided between the sixth partial region r6 and the second electrode portion 53b in the third direction D3.

As shown in FIG. 2, at least a part of the first electrode portion 53a is located between the first semiconductor portion 21 and the second semiconductor portion 22 in the second direction D2.

As shown in FIG. 3, at least a part of the first electrode portion 53a is located between the fourth semiconductor portion 24 and the third semiconductor portion 23 in the first direction D1.

As shown in FIGS. 2 and 3, a trench 53T is provided in the semiconductor member 10M including the first semiconductor layer 10 and the second semiconductor layer 20. The first electrode portion 53a is provided in the trench 53T (or recess). The second electrode portion 53b is provided outside the trench 53T.

In the semiconductor device 110, current flowing between the first electrode 51 and the second electrode 52 can be controlled by a potential of the third electrode 53. The potential of the third electrode 53 may be based on a potential of the first electrode 51. The first electrode 51 functions, for example, as a source electrode. The second electrode 52 functions, for example, as a drain electrode. The third electrode 53 functions as, for example, a gate electrode. The semiconductor device 110 is, for example, a transistor.

The first semiconductor layer 10 includes a portion facing the second semiconductor layer 20. A carrier region is formed in this portion. The carrier region is, for example, a two-dimensional electron gas. The semiconductor device 110 is, for example, a HEMT (High Electron Mobility Transistor).

For example, the distance between the first electrode 51 and the third electrode 53 is shorter than the distance between the third electrode 53 and the second electrode 52. It becomes to obtain a stable operation.

As described above, the first electrode portion 53a is provided in the trench 53T. Thereby, it becomes easy to obtain a high threshold voltage. For example, normally-off operation is obtained. In the semiconductor device 110, the first electrode portion 53a may be provided between the fourth partial region r4 and the fifth partial region r5.

As shown in FIG. 3, a first electrode portion thickness t1 of the first electrode portion 53a along the third direction D3 is thicker than a second electrode portion thickness t2 of the second electrode portion 53b along the third direction D3. For example, low electrical resistance can be obtained by increasing the first electrode portion thickness t1. For example, stable switching operation is possible.

In one example, a high resistance region 10i may be formed by selectively implanting ions or the like into the peripheral region of the semiconductor member 10M (see FIG. 3). A region into which ions or the like are not implanted corresponds to an active region.

For example, ions or the like may be implanted into the semiconductor member 10M via the second electrode portion 53b. By the second electrode portion 53b being thin, the high resistance region 10i can be stably obtained. For example, leakage current can be effectively suppressed. According to the embodiment, a semiconductor device with improved characteristics can be provided.

As shown in FIG. 3, the third electrode 53 may further include a third electrode portion 53c. The third electrode portion 53c is provided between the first electrode portion 53a and the second electrode portion 53b. The third electrode portion 53c is electrically connected to the first electrode portion 53a and the second electrode portion 53b. The third electrode portion 53c is provided between at least a part of the first electrode portion 53a and the third semiconductor portion 23. The third electrode portion 53c is provided, for example, in the trench 53T.

As shown in FIG. 3, the first electrode portion thickness t1 is thicker than a third electrode portion thickness t3 of the third electrode portion 53c along the third direction D3. By the third electrode portion thickness t3 being thin, the high resistance region 10i can be stably obtained by, for example, implanting ions through the third electrode portion 53c.

As shown in FIG. 3, the third electrode 53 may further include a fourth electrode portion 53d. The fourth electrode portion 53d is electrically connected to the first electrode portion 53a. The fourth semiconductor portion 24 is provided between the seventh partial region r7 and the fourth electrode portion 53d in the third direction D3. The first electrode portion thickness t1 is thicker than a fourth electrode portion thickness t4 of the fourth electrode portion 53d along the third direction D3. By the fourth electrode portion thickness t4 being thin, the high resistance region 10i can be stably obtained by, for example, implanting ions through the fourth electrode portion 53d.

As shown in FIG. 3, the third electrode 53 may further include a fifth electrode portion 53e. The fifth electrode portion 53e is provided between the fourth electrode portion 53d and the first electrode portion 53a. The fifth electrode portion 53e is electrically connected to the fourth electrode portion 53d and the first electrode portion 53a. The fifth electrode portion 53e is provided between the fourth semiconductor portion 24 and at least a part of the first electrode portion 53a. The first electrode portion thickness t1 is thicker than a fifth electrode portion thickness t5 of the fifth electrode portion 53e along the third direction D3. By the fifth electrode portion thickness t5 being thin, the high resistance region 10i can be stably obtained by, for example, implantation of ions through the fifth electrode portion 53e.

For example, as shown in FIG. 1, the semiconductor device 110 may include a first region R1, a second region R2, and a third region R3. The first region R1 is provided between the second region R2 and the third region R3 in the first direction D1. The first region R1 is an active region. The second region R2 is one of the plurality of terminal regions. The third region R3 is another one of the plurality of terminal regions. The electrical resistance in the second region R2 and the third region R3 is higher than the electrical resistance in the first region R1. For example, the second region R2 and the third region R3 include the high resistance region 10i. The first region R1 does not include the high resistance region 10i. The first region R1, the second region R2, and the third region R3 are included in the semiconductor member 10M. The first region R1, the second region R2, and the third region R3 are regions of the semiconductor member 10M on the electrode side.

In the embodiment, leak paths can be stably suppressed around the end of the third electrode 53 in the Y-axis direction. The first partial region r1, the second partial region r2, the third partial region r3, the fourth partial region r4, and the fifth partial region r5 are included in the first region R1. The sixth partial region r6 and the third semiconductor portion 23 are included in the second region R2. The crystallinity of the first region R1 is higher than the crystallinity of the second region R2. Alternatively, the first region R1 includes crystal, and the second region R2 does not include crystal.

The seventh partial region r7 and the fourth semiconductor portion 24 are included in the third region R3. The crystallinity of the first region R1 is higher than the crystallinity of the third region R3. Alternatively, the first region R1 includes crystal, and the third region R3 does not include crystal.

The second region R2 and the third region R3 are formed, for example, by implanting ions such as Ar into the semiconductor layer to deteriorate the crystallinity of the semiconductor layer. The first region R1 is a region into which ions are not implanted. The concentration of the first element in the second region R2 and the third region R3 is higher than the concentration of the first element in the first region R1. The first element includes at least one selected from the group consisting of Ar, P, and N.

For example, the crystallinity of the first semiconductor portion 21 is higher than the crystallinity of at least a part of the third semiconductor portion 23. Alternatively, the first semiconductor portion 21 includes crystal, and at least a part of the third semiconductor portion 23 does not include crystal. For example, the crystallinity of the first semiconductor portion 21 is higher than the crystallinity of at least a part of the fourth semiconductor portion 24. Alternatively, the first semiconductor portion 21 includes crystal, and at least a part of the fourth semiconductor portion 24 does not include crystal.

For example, the crystallinity of the third partial region r3 is higher than the crystallinity of the sixth partial region r6. Alternatively, the third partial region r3 includes crystal, and the sixth partial region r6 does not include crystal. For example, the crystallinity of the third partial region r3 is higher than the crystallinity of the seventh partial region r7. Alternatively, the third partial region r3 includes crystal, and the seventh partial region r7 does not include crystal.

For example, as shown in FIG. 3, the second region R2 includes the high resistance region 10i. The high resistance region 10i is a region into which ions such as Ar are implanted. The sixth partial region r6 and the third semiconductor portion 23 are included in the high resistance region 10i. The crystallinity in these regions included in the high resistance region 10i is lower than the crystallinity in the region (first region R1) not included in the high resistance region 10i.

For example, a direction from at least a part of the fourth electrode portion 53d to the first electrode portion 53a may be along the first direction D1. A direction from the first electrode portion 53a to at least a part of the second electrode portion 53b may be along the first direction D1.

In the embodiment, at least a part of the third electrode 53 may include polysilicon. For example, the first electrode portion 53a includes polysilicon. By the first electrode portion 53a including polysilicon, for example, fluctuations in threshold voltage are suppressed. For example, it is thought that electrical characteristics near the gate region are stabilized.

For example, the electrical resistance of polysilicon is higher than the electrical resistance of a material including metal, for example. When the first electrode portion 53a includes polysilicon, by the first electrode portion thickness t1 being thick, the electrical resistance of the first electrode portion 53a can be effectively reduced.

In the embodiment, the first electrode portion thickness t1 may be not less than 1.5 times the second electrode portion thickness t2. The first electrode portion thickness t1 may be not less than two times the second electrode portion thickness t2. The first electrode portion thickness t1 may be not less than five times the second electrode portion thickness t2.

As shown in FIG. 3, a length of the first electrode portion 53a along the first direction D1 is defined as the first electrode portion length L1. The first electrode portion length L1 is longer than a second electrode portion length L2 of the second electrode portion 53b along the first direction D1. The first electrode portion length L1 is longer than a third electrode portion length L3 of the third electrode portion 53c along the first direction D1.

The first electrode portion length L1 is longer than a fourth electrode portion length L4 of the fourth electrode portion 53d along the first direction D1. The first electrode portion length L1 is longer than a fifth electrode portion length L5 of the fifth electrode portion 53e along the first direction D1.

As shown in FIG. 3, for example, a position of a first boundary BD1 between the third partial region r3 and at least a part of the sixth partial region r6 in the first direction D1 may be substantially coincide with a position of a second boundary BD2 between the first electrode portion 53a and the third electrode portion 53c in the first direction D1.

For example, the position of the first boundary BD1 between the third partial region r3 and at least a part of the sixth partial region r6 in the first direction D1 may be between a position in the first direction of the second boundary BD2 between the first electrode portion 53a and the third electrode portion 53c, and the position of the third semiconductor portion 23 in the first direction D1.

As shown in FIGS. 2 and 3, the semiconductor device 110 may further include a nitride member 31. The nitride member 31 includes Al_{z1}Ga_{1-z1}N (0<z1≤1, x2<z1). The composition ratio z1 may be, for example, not less than 0.9 and not more than 1. The nitride member 31 may include AlN.

The nitride member 31 includes a first nitride region 31a. The first nitride region 31a is provided between the third partial region r3 and the first electrode portion 53a in the third direction D3. By providing the nitride member 31, for example, high mobility can be obtained. For example, low on-resistance can be obtained.

As shown in FIGS. 2 and 3, the semiconductor device 110 may further include a first insulating member 41. The first insulating member 41 includes a first insulating region 41a. The first insulating region 41a is provided between the first nitride region 31a and the first electrode portion 53a. The first insulating member 41 includes silicon and at least one selected from the group consisting of oxygen and nitrogen. The first insulating member 41 includes, for example, silicon oxide (e.g., SiO₂).

As shown in FIG. 2, the semiconductor device 110 may further include a second insulating member 42. The second insulating member 42 includes a first insulating portion 42a and a second insulating portion 42b. The first semiconductor portion 21 is provided between the fourth partial region r4 and the first insulating portion 42a in the third direction D3. The second semiconductor portion 22 is provided between the fifth partial region r5 and the second insulating portion 42b in the third direction D3. The second insulating member 42 includes silicon and at least one selected from the group consisting of oxygen and nitrogen. The second insulating member 42 includes, for example, silicon nitride (e.g., SiN).

As shown in FIGS. 2 and 3, in this example, the semiconductor device 110 includes a substrate 10S and a nitride layer 10B. The nitride layer 10B is provided between the substrate 10S and the first semiconductor layer 10. The substrate 10S may be, for example, a silicon substrate. The nitride layer 10B may include, for example, Al, Ga, and nitrogen. The nitride layer 10B is, for example, a buffer layer.

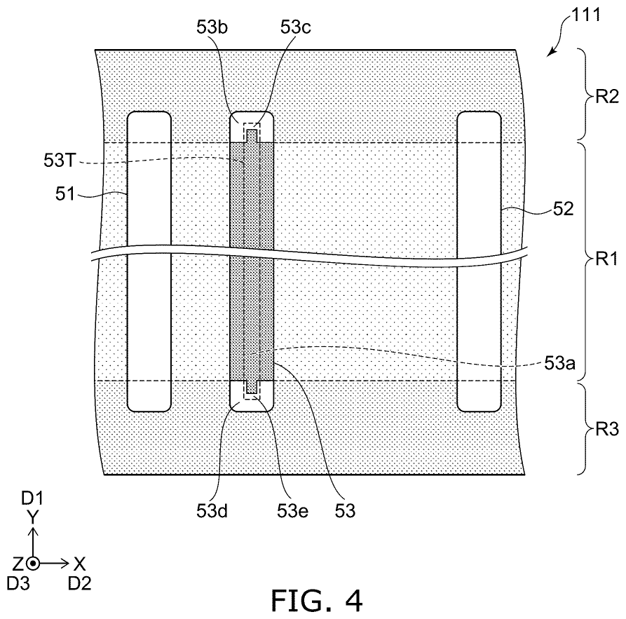

FIG. 4 is a schematic plan view illustrating a semiconductor device according to the first embodiment.

As shown in FIG. 4, in a semiconductor device 111 according to the embodiment, the pattern of the first electrode portion 53a being thick is different from that in the semiconductor device 110. The configuration of the semiconductor device 111 other than this may be the same as the configuration of the semiconductor device 110.

In the third electrode 53 of the semiconductor device 111, the width in the second direction D2 of the thick portion corresponding to the second region R2 is narrower than the width in the second direction D2 of the portion corresponding to the first region R1. In the embodiment, the pattern of the thick portion and thin portion of the third electrode 53 can be changed in various ways.

### Second Embodiment

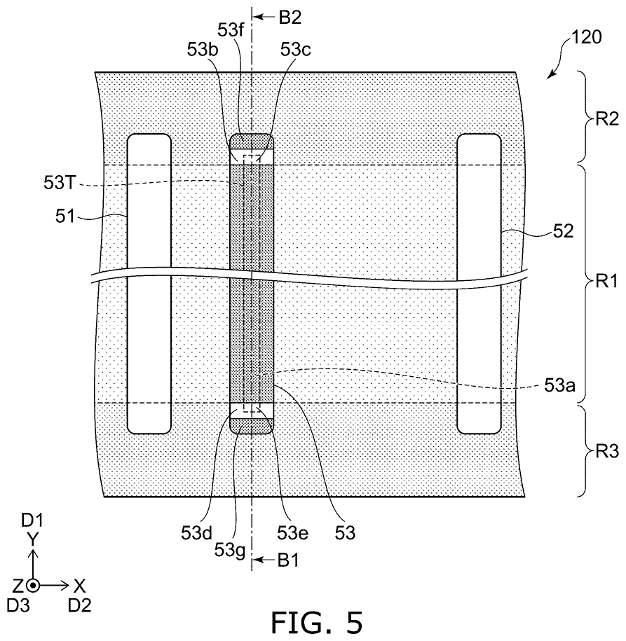

FIG. 5 is a schematic plan view illustrating a semiconductor device according to the second embodiment.

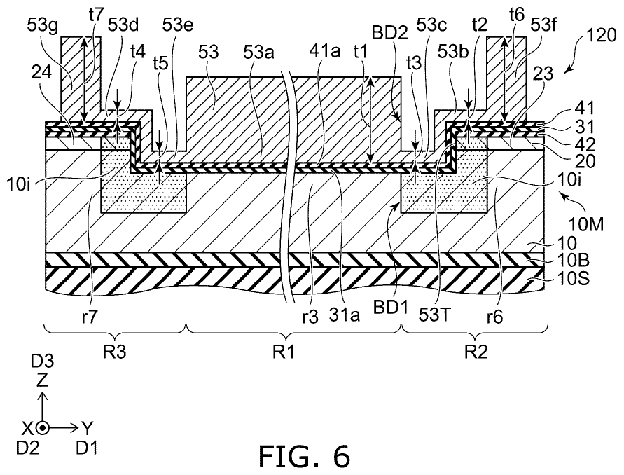

FIG. 6 is a schematic cross-sectional view illustrating the semiconductor device according to the second embodiment.

FIG. 6 is a sectional view taken along the line B1-B2 in FIG. 5.

As shown in FIGS. 5 and 6, the configuration of the third electrode 53 in a semiconductor device 120 according to the embodiment is different from the configuration in the semiconductor device 110. The configuration of the semiconductor device 120 except for this may be the same as the configuration of the semiconductor device 110.

In the semiconductor device 120, the third electrode 53 further includes a sixth electrode portion 53f in addition to the first electrode portion 53a and the second electrode portion 53b. The second electrode portion 53b is provided between the first electrode portion 53a and the sixth electrode portion 53f. The sixth electrode portion 53f is electrically connected to the second electrode portion 53b. A part of the third semiconductor portion 23 is provided between the sixth partial region r6 and the sixth electrode portion 53f in the third direction D3. A sixth electrode portion thickness t6 of the sixth electrode portion 53f along the third direction D3 is thicker than the second electrode portion thickness t2.

In the semiconductor device 120, the third electrode 53 may further include a seventh electrode portion 53g. The fourth electrode portion 53d is provided between the seventh electrode portion 53g and the first electrode portion 53a. The seventh electrode portion 53g is electrically connected to the fourth electrode portion 53d. A part of the fourth semiconductor portion 24 is provided between the seventh partial region r7 and the seventh electrode portion 53g in the third direction D3. A seventh electrode portion thickness t7 of the seventh electrode portion 53g along the third direction D3 is thicker than the fourth electrode portion thickness t4.

Also in the semiconductor device 120, by providing the second electrode portion 53b and the fourth electrode portion 53d being thin, the high resistance region 10i can be stably formed. Leak paths can be stably suppressed.

By providing the sixth electrode portion 53f and seventh electrode portion 53g being thick, for example, when wiring is provided on the third electrode 53 via an insulating film, connection between these electrode portions and the wiring becomes easy. For example, the resistance of the third electrode 53 can be easily reduced. For example, it becomes easier to obtain more stable characteristics.

In the embodiments, information regarding length and thickness is obtained by electron microscopy or the like. Information regarding the composition of the material can be obtained by SIMS (Secondary Ion Mass Spectrometry), EDX (Energy dispersive X-ray spectroscopy), or the like.

Embodiments may include the following Technical proposals:

### Technical Proposal 1

A semiconductor device, comprising:
a first electrode extending along a first direction;
a second electrode extending along the first direction, a second direction from the first electrode to the second electrode crossing the first direction;
a third electrode extending along the first direction, a position of the third electrode in the second direction being between a position of the first electrode in the second direction and a position of the second electrode in the second direction, the third electrode including a first electrode portion and a second electrode portion, the second electrode portion being electrically connected to the first electrode portion; and
a semiconductor member,
the semiconductor member including
   a first semiconductor layer including Alₓ₁Ga₁₋ₓ₁N (0≤x1<1), and
   a second semiconductor layer including Alₓ₂Ga₁₋ₓ₂N (0<x2≤1, x1<x2),
the first semiconductor layer including a first partial region, a second partial region, a third partial region, a fourth partial region, a fifth partial region, a sixth partial region, and a seventh partial region,
a direction from the first partial region to the first electrode being along a third direction crossing a plane including the first direction and the second direction,
a direction from the second partial region to the second electrode being along the third direction,
a direction from the third partial region to the first electrode portion being along the third direction,
a position of the fourth partial region in the second direction being between a position of the first partial region in the second direction and a position of the third partial region in the second direction,
the position of the fifth partial region in the second direction being between the position of the third partial region in the second direction and a position of the second partial region in the second direction,
a position of the third partial region in the first direction being between a position of the seventh partial region in the first direction and a position of the sixth partial region in the first direction,
the second semiconductor layer including a first semiconductor portion, a second semiconductor portion, a third semiconductor portion, and a fourth semiconductor portion,
a direction from the fourth partial region to the first semiconductor portion being along the third direction,
a direction from the fifth partial region to the second semiconductor portion being along the third direction,
a direction from the sixth partial region to the third semiconductor portion being along the third direction,
a direction from the seventh partial region to the fourth semiconductor portion being along the third direction,
the third semiconductor portion being provided between the sixth partial region and the second electrode portion in the third direction,
at least a part of the first electrode portion being between the first semiconductor portion and the second semiconductor portion in the second direction,
the at least the part of the first electrode portion being between the fourth semiconductor portion and the third semiconductor portion in the first direction,
a first electrode portion thickness of the first electrode portion along the third direction being thicker than a second electrode portion thickness of the second electrode portion along the third direction,
the third electrode further including a third electrode portion,
the third electrode portion being provided between the first electrode portion and the second electrode portion,
the third electrode portion being electrically connected to the first electrode portion and the second electrode portion,
the third electrode portion being provided between the at least the part of the first electrode portion and the third semiconductor portion, and
the first electrode portion thickness being thicker than a third electrode portion thickness of the third electrode portion along the third direction.

### Technical Proposal 2

The semiconductor device according to Technical proposal 1, wherein
at least a part of the third electrode includes polysilicon.

### Technical Proposal 3

A semiconductor device, comprising:
a first electrode extending along a first direction;
a second electrode extending along the first direction, a second direction from the first electrode to the second electrode crossing the first direction;
a third electrode extending along the first direction, a position of the third electrode in the second direction being between a position of the first electrode in the second direction and a position of the second electrode in the second direction, the third electrode including a first electrode portion and a second electrode portion, the second electrode portion being electrically connected to the first electrode portion; and
a semiconductor member,
the semiconductor member including
   a first semiconductor layer including Alₓ₁Ga₁₋ₓ₁N (0≤x1<1), and
   a second semiconductor layer including Alₓ₂Ga₁₋ₓ₂N (0<x2≤1, x1<x2),
the first semiconductor layer including a first partial region, a second partial region, a third partial region, a fourth partial region, a fifth partial region, a sixth partial region, and a seventh partial region,
a direction from the first partial region to the first electrode being along a third direction crossing a plane including the first direction and the second direction,
a direction from the second partial region to the second electrode being along the third direction,
a direction from the third partial region to the first electrode portion being along the third direction,
a position of the fourth partial region in the second direction being between a position of the first partial region in the second direction and a position of the third partial region in the second direction,
the position of the fifth partial region in the second direction being between the position of the third partial region in the second direction and a position of the second partial region in the second direction,
a position of the third partial region in the first direction being between a position of the seventh partial region in the first direction and a position of the sixth partial region in the first direction,
the second semiconductor layer including a first semiconductor portion, a second semiconductor portion, a third semiconductor portion, and a fourth semiconductor portion,
a direction from the fourth partial region to the first semiconductor portion being along the third direction,
a direction from the fifth partial region to the second semiconductor portion being along the third direction,
a direction from the sixth partial region to the third semiconductor portion being along the third direction,
a direction from the seventh partial region to the fourth semiconductor portion being along the third direction,
the third semiconductor portion being provided between the sixth partial region and the second electrode portion in the third direction,
at least a part of the first electrode portion being between the first semiconductor portion and the second semiconductor portion in the second direction,
the at least the part of the first electrode portion being between the fourth semiconductor portion and the third semiconductor portion in the first direction,
a first electrode portion thickness of the first electrode portion along the third direction being thicker than a second electrode portion thickness of the second electrode portion along the third direction, and
at least a part of the third electrode including polysilicon.

### Technical Proposal 4

The semiconductor device according to any one of Technical proposals 1-3, wherein
the first electrode portion includes polysilicon.

### Technical Proposal 5

The semiconductor device according to any one of Technical proposals 1-4, wherein
a crystallinity of the first semiconductor portion is higher than a crystallinity of at least a part of the third semiconductor portion, or
the first semiconductor portion includes crystal, and the at least a part of the third semiconductor portion does not include crystal.

### Technical Proposal 6

The semiconductor device according to any one of Technical proposals 1-4, wherein
the third electrode further includes a fourth electrode portion,
the fourth electrode portion is electrically connected to the first electrode portion,
the fourth semiconductor portion is provided between the seventh partial region and the fourth electrode portion in the third direction, and
the first electrode portion thickness is thicker than a fourth electrode portion thickness of the fourth electrode portion along the third direction.

### Technical Proposal 7

The semiconductor device according to Technical proposal 6, wherein
the third electrode further includes a fifth electrode portion,
the fifth electrode portion is provided between the fourth electrode portion and the first electrode portion,
the fifth electrode portion is electrically connected to the fourth electrode portion and the first electrode portion,
the fifth electrode portion is provided between the fourth semiconductor portion and the at least the part of the first electrode portion, and
the first electrode portion thickness is thicker than a fifth electrode portion thickness along the third direction of the fifth electrode portion.

### Technical Proposal 8

The semiconductor device according to Technical proposal 6 or 7, wherein
a crystallinity of the first semiconductor portion is higher than a crystallinity of at least a part of the fourth semiconductor portion, or
the first semiconductor portion includes crystal, and the at least the part of the fourth semiconductor portion does not include crystal.

### Technical Proposal 9

The semiconductor device according to any one of Technical proposals 6-8, wherein
a direction from at least a part of the fourth electrode portion to the first electrode portion is along the first direction.

### Technical Proposal 10

The semiconductor device according to any one of Technical proposals 1-9, wherein
a direction from the first electrode portion to at least a part of the second electrode portion is along the first direction.

### Technical Proposal 11

The semiconductor device according to any one of Technical proposals 1-10, further comprising:
a nitride member including Al_{z1}Ga_{1-z1}N (0<z1≤1, x2<z1),
the nitride member including a first nitride region, and
the first nitride region being provided between the third partial region and the first electrode portion in the third direction.

### Technical Proposal 12

The semiconductor device according to Technical proposal 11, further comprising:
a first insulating member,
the first insulating member including a first insulating region,
the first insulating region being provided between the first nitride region and the first electrode portion, and
the first insulating member including silicon and at least one selected from the group consisting of oxygen and nitrogen.

### Technical Proposal 13

The semiconductor device according to any one of Technical proposals 1-12, further comprising:
a second insulating member,
the second insulating member including a first insulating portion and a second insulating portion,
the first semiconductor portion being provided between the fourth partial region and the first insulating portion in the third direction,
the second semiconductor portion being provided between the fifth partial region and the second insulating portion in the third direction, and
the second insulating member including silicon and at least one selected from the group consisting of oxygen and nitrogen.

### Technical Proposal 14

The semiconductor device according to Technical proposal 1, wherein
the third electrode further includes a sixth electrode portion,
the second electrode portion is provided between the first electrode portion and the sixth electrode portion,
the sixth electrode portion is electrically connected to the second electrode portion, and
a sixth electrode portion thickness of the sixth electrode portion along the third direction is thicker than the second electrode portion thickness.

### Technical Proposal 15

The semiconductor device according to Technical proposal 6, wherein
the third electrode further includes a seventh electrode portion,
the fourth electrode portion is provided between the seventh electrode portion and the first electrode portion,
the seventh electrode portion is electrically connected to the fourth electrode portion, and
a seventh electrode portion thickness of the seventh electrode portion along the third direction is thicker than the fourth electrode portion thickness.

### Technical Proposal 16

The semiconductor device according to any one of Technical proposals 1-15, wherein
a first electrode portion length of the first electrode portion along the first direction is longer than a second electrode portion length of the second electrode portion along the first direction.

### Technical Proposal 17

The semiconductor device according to Technical proposal 1, wherein
a first electrode portion length of the first electrode portion along the first direction is longer than a third electrode portion length of the third electrode portion along the first direction.

### Technical Proposal 18

The semiconductor device according to Technical proposal 1, wherein
a crystallinity of the third partial region is higher than a crystallinity of at least a part of the sixth partial region, or
the third partial region includes crystal, and the at least the part of the sixth partial region does not include crystal, and
a position of a first boundary between the third partial region and the at least the part of the sixth partial region in the first direction substantially coincides with a position of a second boundary between the first electrode portion and the third electrode portion in the first direction.

### Technical Proposal 19

The semiconductor device according to Technical proposal 1, wherein
a crystallinity of the third partial region is higher than a crystallinity of at least a part of the sixth partial region, or
the third partial region includes crystal, and the at least the part of the sixth partial region does not includes crystal, and
a position of a first boundary between the third partial region and the at least the part of the sixth partial region in the first direction is between a position in the first direction of a second boundary between the first electrode portion and the third electrode portion, and a position of the third semiconductor portion in the first direction.

### Technical Proposal 20

The semiconductor device according to any one of Technical proposals 1-19, wherein
the first electrode portion thickness is not less than 1.5 times the second electrode portion thickness.

### Technical Proposal 21

The semiconductor device according to Technical proposal 3, wherein
a crystallinity of the third partial region is higher than a crystallinity of at least a part of the sixth partial region, or
the third partial region includes crystal, and the at least the part of the sixth partial region does not includes crystal, and
a position of a first boundary between the third partial region and the at least the part of the sixth partial region in the first direction substantially coincides with a position of a third boundary between the first electrode portion and the second electrode portion in the first direction.

### Third Embodiment

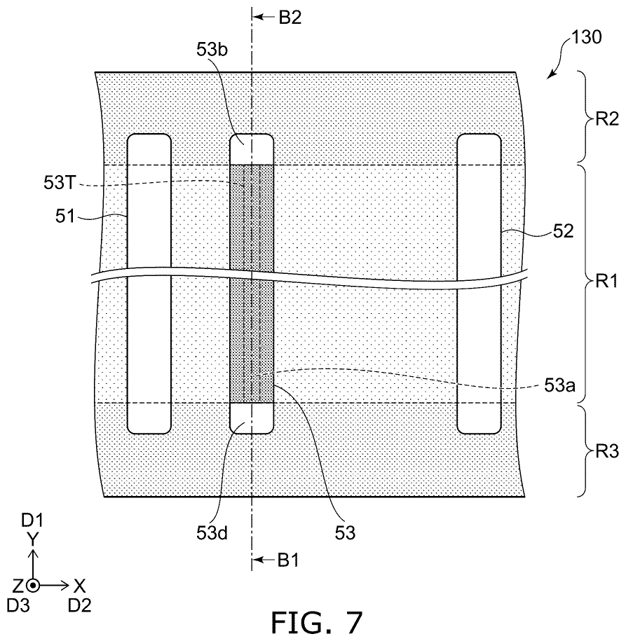

FIG. 7 is a schematic plan view illustrating a semiconductor device according to a third embodiment.

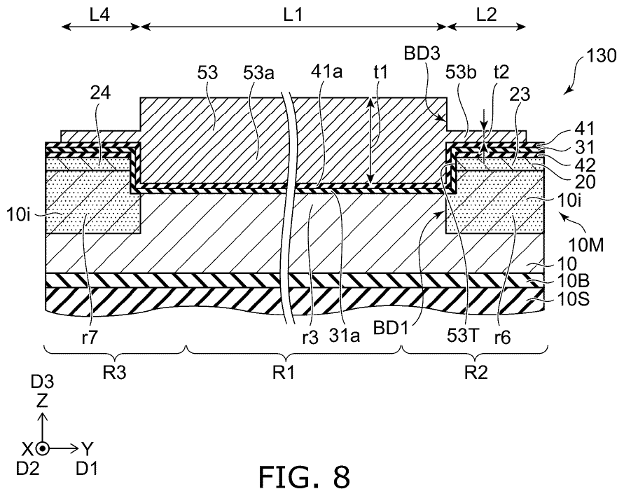

FIG. 8 is a schematic cross-sectional view illustrating the semiconductor device according to the third embodiment.

FIG. 8 is a sectional view taken along the line B1-B2 in FIG. 7.

As shown in FIGS. 7 and 8, in a semiconductor device 130 according to the embodiment, the third electrode portion 53c and the fifth electrode portion 53e are omitted. The configuration of the semiconductor device 130 except for this may be the same as the configuration of the semiconductor device 110. In semiconductor device 130, at least a part of third electrode 53 includes polysilicon. Also in the semiconductor device 130, for example, leakage current can be effectively suppressed. According to the embodiment, a semiconductor device with improved characteristics can be provided.

As shown in FIG. 8, for example, the position in the first direction D1 of a first boundary BD1 between the third partial region r3 and at least a part of the sixth partial region r6 may substantially coincide with a position in the first direction D1 of a third boundary BD3 between the first electrode portion 53a and the second electrode portion 53b.

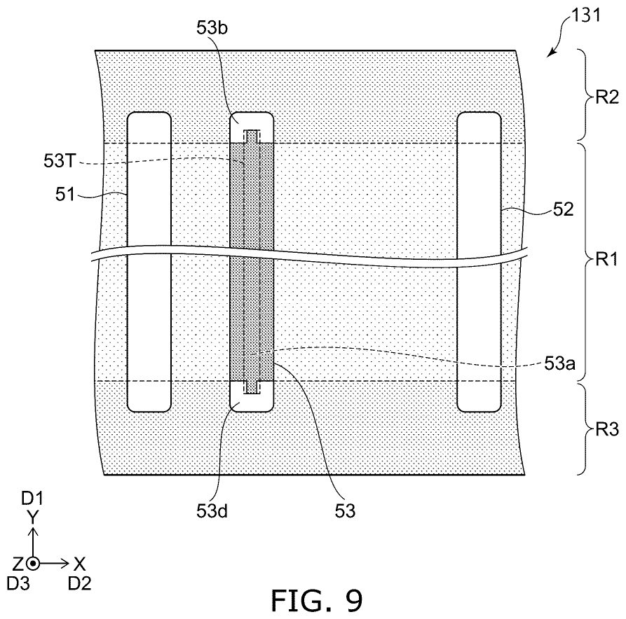

FIG. 9 is a schematic plan view illustrating a semiconductor device according to the third embodiment.

As shown in FIG. 9, in a semiconductor device 131 according to the embodiment, the third electrode portion 53c and the fifth electrode portion 53e are also omitted. The configuration of the semiconductor device 131 except for this may be the same as that of the semiconductor device 111. In semiconductor device 131, at least a part of third electrode 53 includes polysilicon. Also in the semiconductor device 131, for example, leakage current can be effectively suppressed. According to the embodiment, a semiconductor device with improved characteristics can be provided.

According to the embodiment, a semiconductor device whose characteristics can be improved can be provided.

In the specification of the application, “perpendicular” and “parallel” refer to not only strictly perpendicular and strictly parallel but also include, for example, the fluctuation due to manufacturing processes, etc. It is sufficient to be substantially perpendicular and substantially parallel.

Hereinabove, exemplary embodiments of the invention are described with reference to specific examples. However, the embodiments of the invention are not limited to these specific examples. For example, one skilled in the art may similarly practice the invention by appropriately selecting specific configurations of components included in the semiconductor device such as semiconductor layers, electrodes, insulating members, etc., from known art. Such practice is included in the scope of the invention to the extent that similar effects thereto are obtained.

Further, any two or more components of the specific examples may be combined within the extent of technical feasibility and are included in the scope of the invention to the extent that the purport of the invention is included.

Moreover, all semiconductor devices practicable by an appropriate design modification by one skilled in the art based on the semiconductor devices described above as embodiments of the invention also are within the scope of the invention to the extent that the purport of the invention is included.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor device, comprising:
a first electrode extending along a first direction;
a second electrode extending along the first direction, a second direction from the first electrode to the second electrode crossing the first direction;
a third electrode extending along the first direction, a position of the third electrode in the second direction being between a position of the first electrode in the second direction and a position of the second electrode in the second direction, the third electrode including a first electrode portion and a second electrode portion, the second electrode portion being electrically connected to the first electrode portion; and
a semiconductor member,
the semiconductor member including
a first semiconductor layer including Alₓ₁Ga₁₋ₓ₁N (0≤x1<1), and
a second semiconductor layer including Alₓ₂Ga₁₋ₓ₂N (0<x2≤1, x1<x2),
the first semiconductor layer including a first partial region, a second partial region, a third partial region, a fourth partial region, a fifth partial region, a sixth partial region, and a seventh partial region,
a direction from the first partial region to the first electrode being along a third direction crossing a plane including the first direction and the second direction,
a direction from the second partial region to the second electrode being along the third direction,
a direction from the third partial region to the first electrode portion being along the third direction,
a position of the fourth partial region in the second direction being between a position of the first partial region in the second direction and a position of the third partial region in the second direction,
the position of the fifth partial region in the second direction being between the position of the third partial region in the second direction and a position of the second partial region in the second direction,
a position of the third partial region in the first direction being between a position of the seventh partial region in the first direction and a position of the sixth partial region in the first direction,
the second semiconductor layer including a first semiconductor portion, a second semiconductor portion, a third semiconductor portion, and a fourth semiconductor portion,
a direction from the fourth partial region to the first semiconductor portion being along the third direction,
a direction from the fifth partial region to the second semiconductor portion being along the third direction,
a direction from the sixth partial region to the third semiconductor portion being along the third direction,
a direction from the seventh partial region to the fourth semiconductor portion being along the third direction,
the third semiconductor portion being provided between the sixth partial region and the second electrode portion in the third direction,
at least a part of the first electrode portion being between the first semiconductor portion and the second semiconductor portion in the second direction,
the at least the part of the first electrode portion being between the fourth semiconductor portion and the third semiconductor portion in the first direction,
a first electrode portion thickness of the first electrode portion along the third direction being thicker than a second electrode portion thickness of the second electrode portion along the third direction,
the third electrode further including a third electrode portion,
the third electrode portion being provided between the first electrode portion and the second electrode portion,
the third electrode portion being electrically connected to the first electrode portion and the second electrode portion,
the third electrode portion being provided between the at least the part of the first electrode portion and the third semiconductor portion, and
the first electrode portion thickness being thicker than a third electrode portion thickness of the third electrode portion along the third direction.

2. The device according to claim 1, wherein
at least a part of the third electrode includes polysilicon.

3. A semiconductor device, comprising:
a first electrode extending along a first direction;
a second electrode extending along the first direction, a second direction from the first electrode to the second electrode crossing the first direction;
a third electrode extending along the first direction, a position of the third electrode in the second direction being between a position of the first electrode in the second direction and a position of the second electrode in the second direction, the third electrode including a first electrode portion and a second electrode portion, the second electrode portion being electrically connected to the first electrode portion; and
a semiconductor member,
the semiconductor member including
a first semiconductor layer including Alₓ₁Ga₁₋ₓ₁N (0≤x1<1), and
a second semiconductor layer including Alₓ₂Ga₁₋ₓ₂N (0<x2≤1, x1<x2),
the first semiconductor layer including a first partial region, a second partial region, a third partial region, a fourth partial region, a fifth partial region, a sixth partial region, and a seventh partial region,
a direction from the first partial region to the first electrode being along a third direction crossing a plane including the first direction and the second direction,
a direction from the second partial region to the second electrode being along the third direction,
a direction from the third partial region to the first electrode portion being along the third direction,
a position of the fourth partial region in the second direction being between a position of the first partial region in the second direction and a position of the third partial region in the second direction,
the position of the fifth partial region in the second direction being between the position of the third partial region in the second direction and a position of the second partial region in the second direction,
a position of the third partial region in the first direction being between a position of the seventh partial region in the first direction and a position of the sixth partial region in the first direction,
the second semiconductor layer including a first semiconductor portion, a second semiconductor portion, a third semiconductor portion, and a fourth semiconductor portion,
a direction from the fourth partial region to the first semiconductor portion being along the third direction,
a direction from the fifth partial region to the second semiconductor portion being along the third direction,
a direction from the sixth partial region to the third semiconductor portion being along the third direction,
a direction from the seventh partial region to the fourth semiconductor portion being along the third direction,
the third semiconductor portion being provided between the sixth partial region and the second electrode portion in the third direction,
at least a part of the first electrode portion being between the first semiconductor portion and the second semiconductor portion in the second direction,
the at least the part of the first electrode portion being between the fourth semiconductor portion and the third semiconductor portion in the first direction,
a first electrode portion thickness of the first electrode portion along the third direction being thicker than a second electrode portion thickness of the second electrode portion along the third direction, and
at least a part of the third electrode including polysilicon.

4. The device according to claim 1, wherein
the first electrode portion includes polysilicon.

5. The device according to claim 1, wherein
a crystallinity of the first semiconductor portion is higher than a crystallinity of at least a part of the third semiconductor portion, or
the first semiconductor portion includes crystal, and the at least a part of the third semiconductor portion does not include crystal.

6. The device according to claim 1, wherein
the third electrode further includes a fourth electrode portion,
the fourth electrode portion is electrically connected to the first electrode portion,
the fourth semiconductor portion is provided between the seventh partial region and the fourth electrode portion in the third direction, and
the first electrode portion thickness is thicker than a fourth electrode portion thickness of the fourth electrode portion along the third direction.

7. The device according to claim 6, wherein
the third electrode further includes a fifth electrode portion,
the fifth electrode portion is provided between the fourth electrode portion and the first electrode portion,
the fifth electrode portion is electrically connected to the fourth electrode portion and the first electrode portion,
the fifth electrode portion is provided between the fourth semiconductor portion and the at least the part of the first electrode portion, and
the first electrode portion thickness is thicker than a fifth electrode portion thickness along the third direction of the fifth electrode portion.

8. The device according to claim 6, wherein
a crystallinity of the first semiconductor portion is higher than a crystallinity of at least a part of the fourth semiconductor portion, or
the first semiconductor portion includes crystal, and the at least the part of the fourth semiconductor portion does not include crystal.

9. The device according to claim 6, wherein
a direction from at least a part of the fourth electrode portion to the first electrode portion is along the first direction.

10. The device according to claim 1, wherein
a direction from the first electrode portion to at least a part of the second electrode portion is along the first direction.

11. The device according to claim 1, further comprising:
a nitride member including Al_{z1}Ga_{1-z1}N (0<z1≤1, x2<z1),
the nitride member including a first nitride region, and
the first nitride region being provided between the third partial region and the first electrode portion in the third direction.

12. The device according to claim 11, further comprising:
a first insulating member,
the first insulating member including a first insulating region,
the first insulating region being provided between the first nitride region and the first electrode portion, and
the first insulating member including silicon and at least one selected from the group consisting of oxygen and nitrogen.

13. The device according to claim 1, further comprising:
a second insulating member,
the second insulating member including a first insulating portion and a second insulating portion,
the first semiconductor portion being provided between the fourth partial region and the first insulating portion in the third direction,
the second semiconductor portion being provided between the fifth partial region and the second insulating portion in the third direction, and
the second insulating member including silicon and at least one selected from the group consisting of oxygen and nitrogen.

14. The device according to claim 1, wherein
the third electrode further includes a sixth electrode portion,
the second electrode portion is provided between the first electrode portion and the sixth electrode portion,
the sixth electrode portion is electrically connected to the second electrode portion, and
a sixth electrode portion thickness of the sixth electrode portion along the third direction is thicker than the second electrode portion thickness.

15. The device according to claim 6, wherein
the third electrode further includes a seventh electrode portion,
the fourth electrode portion is provided between the seventh electrode portion and the first electrode portion,
the seventh electrode portion is electrically connected to the fourth electrode portion, and
a seventh electrode portion thickness of the seventh electrode portion along the third direction is thicker than the fourth electrode portion thickness.

16. The device according to claim 1, wherein
a first electrode portion length of the first electrode portion along the first direction is longer than a second electrode portion length of the second electrode portion along the first direction.

17. The device according to claim 1, wherein
a first electrode portion length of the first electrode portion along the first direction is longer than a third electrode portion length of the third electrode portion along the first direction.

18. The device according to claim 1, wherein
a crystallinity of the third partial region is higher than a crystallinity of at least a part of the sixth partial region, or
the third partial region includes crystal, and the at least the part of the sixth partial region does not include crystal, and
a position of a first boundary between the third partial region and the at least the part of the sixth partial region in the first direction substantially coincides with a position of a second boundary between the first electrode portion and the third electrode portion in the first direction.

19. The device according to claim 1, wherein
a crystallinity of the third partial region is higher than a crystallinity of at least a part of the sixth partial region, or
the third partial region includes crystal, and the at least the part of the sixth partial region does not includes crystal, and
a position of a first boundary between the third partial region and the at least the part of the sixth partial region in the first direction is between a position in the first direction of a second boundary between the first electrode portion and the third electrode portion, and a position of the third semiconductor portion in the first direction.

20. The device according to claim 1, wherein
the first electrode portion thickness is not less than 1.5 times the second electrode portion thickness.
